(19) United States
(12) Patent Application Publication
(10) Pub. No.: US 2026/0068202 A1
(43) Pub. Date: Mar. 5, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Ryohei GEJO, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/034,715

(22) Filed: Jan. 23, 2025

(30) Foreign Application Priority Data
Aug. 28, 2024 (JP) 2024-146933

(51) Int. Cl. H10D 12/00; H10D 62/10; H10D 62/17

(52) U.S. Cl. CPC H10D 12/481; H10D 62/126; H10D 62/393

(57) ABSTRACT

A semiconductor device according to one embodiment includes a semiconductor layer including a cell region and a termination region that surrounds the cell region, a first insulation film provided on the semiconductor layer, and a semi-insulation film provided on the first insulation film. Further, the semiconductor layer includes: a first semiconductor part of a first conductive type provided in the cell region and the termination region, and a second semiconductor part of a second conductive type provided on the first semiconductor part in the termination region, the second semiconductor part including a plurality of concentration peak regions having a highest concentration of an impurity of the second conductive type in the second semiconductor part. In addition, an end portion on a side of the termination region of the first insulation film is positioned between any two of the plurality of concentration peak regions.

### CROSS-REFERENCE TO RELATED APPLICATIONS

This application is based upon and claims the benefit of priority from Japanese Patent Application No. 2024-146933, filed on Aug. 28, 2024; the entire contents of which are incorporated herein by reference.

### FIELD

Embodiments of the present invention relate to a semiconductor device.

### BACKGROUND

For a semiconductor device used for power control, for example, a termination structure provided with a semi-insulation film to reduce a termination region has been proposed. However, depending on the position of the semi-insulation film, required withstand voltage cannot be secured in some cases.

### BRIEF DESCRIPTION OF THE DRAWINGS

FIG. 1 is a plan view schematically showing a semiconductor device according to a first embodiment;

FIG. 2 is a cross sectional view taken along a cut-line A-A shown in FIG. 1;

FIG. 3 is a cross sectional view showing the structure of a first simulation model;

FIG. 4 is a cross sectional view showing the structure of a second simulation model;

FIG. 5 is a cross sectional view showing the structure of a third simulation model;

FIG. 6 is a cross sectional view showing the structure of a fourth simulation model;

FIG. 7 is a cross sectional view showing the structure of a fifth simulation model;

FIG. 8 is a graph showing results of a TCAD simulation of withstand voltage characteristics conducted using each simulation model; and

FIG. 9 is a cross sectional view of a semiconductor device according to a second embodiment.

### DETAILED DESCRIPTION

Embodiments will now be explained with reference to the accompanying drawings. The present invention is not limited to the embodiments.

A semiconductor device according to one embodiment includes a semiconductor layer having a cell region and a termination region that surrounds the cell region, a first insulation film provided on the semiconductor layer, and a semi-insulation film provided on the first insulation film. Further, the semiconductor layer includes a first semiconductor part of a first conductive type provided in the cell region and the termination region and a second semiconductor part of a second conductive type provided on the first semiconductor part in the termination region, the second semiconductor part having a plurality of concentration peak regions having the highest concentration of an impurity of the second conductive type in the second semiconductor part. Furthermore, an end portion on a side of the termination region of the first insulation film is positioned between any two of the plurality of concentration peak regions.

### First Embodiment

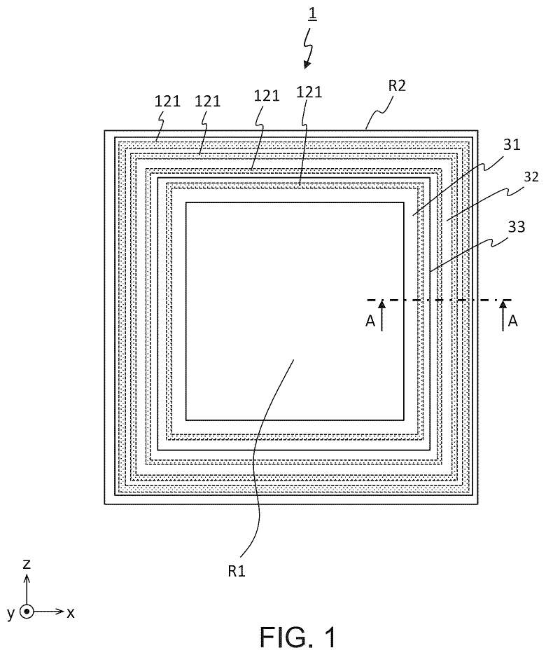

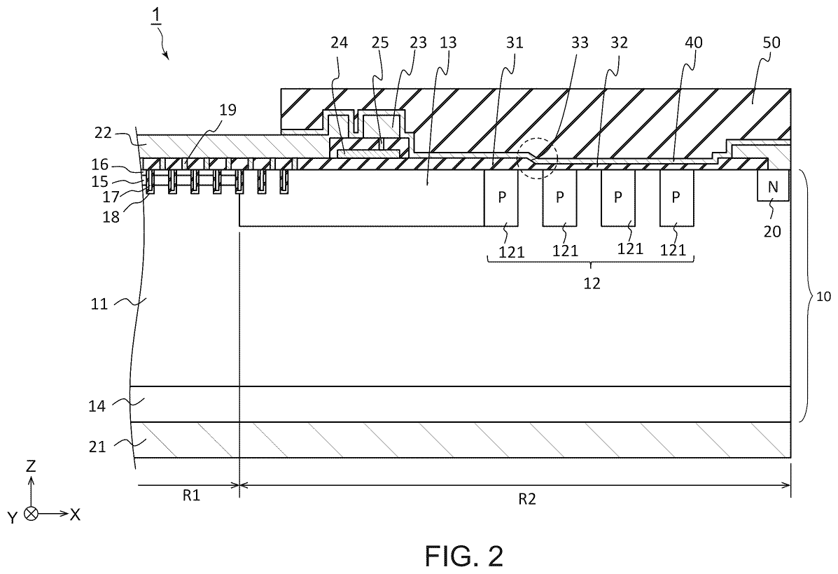

FIG. 1 is a plan view schematically showing a semiconductor device according to a first embodiment. Further, FIG. 2 is a cross sectional view taken along a cut-line A-A shown in FIG. 1.

In the following descriptions, the arrangement and the configuration of parts of the semiconductor device are described using an X-axis, a Y-axis, and a Z-axis shown in each drawing in some cases. The X-axis, the Y-axis, and the Z-axis are mutually orthogonal to each other, representing an X-direction, a Y-direction, and a Z-direction, respectively. Further, descriptions will be made referring to the Z-direction as an upper side and the opposite direction as a lower side in some cases.

Further, notation of p, p⁺ means that the p-type impurity concentration increases in this order. In addition, notation of n⁻, n, n⁺ means that the n-type impurity concentration increases in this order.

An impurity concentration can be measured by, for example, a SIMS (Secondary Ion Mass Spectrometry). Further, a relative level in impurity concentration can also be determined by, for example, determination of the level in a carrier concentration obtained by a SCM (Scanning Capacitance Microscopy). Furthermore, a distance such as a depth of the semiconductor region can be obtained by, for example, the SIMS.

For a semiconductor device 1 shown in FIG. 1, for example, an IGBT (Insulated Gate Bipolar Transistor), an IEGT (Injection Enhanced Gate Transistor), or a diode can be applied. The semiconductor device 1 according to the present embodiment includes a semiconductor layer 10, a first electrode 21, a second electrode 22, and a third electrode 23. When the semiconductor device 1 is a diode, the third electrode 23 is unnecessary.

The semiconductor layer 10 is composed of, for example, a silicon substrate. The semiconductor layer 10 includes, for example, a back surface where the first electrode 21 is provided and a front surface on the opposite side. On a side of the front surface of the semiconductor layer 10, the second electrode 22 and the third electrode 23 are provided. The semiconductor layer 10 includes a cell region R1 and a termination region R2.

The cell region R1 is switched between an ON-state and an OFF-state in accordance with a voltage applied to the third electrode 23. In the ON-state, a current path of a current flowing from the first electrode 21 to the second electrode 22 is formed. In the OFF-state, the aforementioned current path is not formed and thus, the current does not flow from the first electrode 21 to the second electrode 22.

The termination region R2 is provided on an outer side of the cell region R1. In the termination region R2, the aforementioned current path is not formed irrespective of whether a voltage is applied to the third electrode 23, and thus, the current does not flow from the first electrode 21 to the second electrode 22.

The semiconductor layer 10 includes a first semiconductor part 11, a second semiconductor part 12, a third semiconductor part 13, a fourth semiconductor part 14, a fifth semiconductor part 15, and a sixth semiconductor part 16. A conductivity type of the first semiconductor part 11 and the sixth semiconductor part 16 is an n-type (first conductive type). Meanwhile, a conductivity type of the second semiconductor part 12, the third semiconductor part 13, the fourth semiconductor part 14, and the fifth semiconductor part 15 is a p-type (second conductive type).

The first semiconductor part 11 is an n⁻-type drift part. The first semiconductor part 11 is provided in each of the cell region R1 and the termination region R2.

The second semiconductor part 12 is a p-type diffusion part. The second semiconductor part 12 is provided on the first semiconductor part 11 in the termination region R2. In the second semiconductor part 12, a plurality of concentration peak regions 121 is provided. Each concentration peak region 121 is a p-type impurity implanting region, having the highest p-type impurity concentration in the second semiconductor part 12.

As shown in FIG. 1, a planar shape of each concentration peak region 121 is a frame shape continuously surrounding the cell region R1. In the present embodiment, a width (length in the X-direction) of each concentration peak region 121 is the same. Meanwhile, a distance between the concentration peak regions 121, in other words, an interval between the concentration peak regions 121 is reduced as the concentration peak regions 121 becomes further away from the cell region R1.

The third semiconductor part 13 is a p⁺-type semiconductor part provided in the termination region R2. The third semiconductor part 13 contacts the innermost concentration peak region 121 among the plurality of concentration peak regions 121, that is, the concentration peak region 121 closest to the cell region R1.

The fourth semiconductor part 14 is provided between the first semiconductor part 11 and the first electrode 21 in the Z-direction and contacts the first electrode 21. The fourth semiconductor part 14 is a p⁺-type semiconductor part in the cell region R1 and is a p⁻-type semiconductor part in the termination region R2.

The fifth semiconductor part 15 is provided on the first semiconductor part 11 in the cell region R1. The fifth semiconductor part 15 is a p⁺-type base part.

The sixth semiconductor part 16 is provided on the fifth semiconductor part 15. The sixth semiconductor part 16 is an n⁺-type contact part. The sixth semiconductor part 16 is electrically connected to the second electrode 22 via a contact via 19.

When the semiconductor device 1 is an IGBT or an IEGT, as shown in FIG. 2, a plurality of trench gates 17 is arranged at a predetermined pitch (for example, 2 μm). Further, on a front surface of an outermost periphery of the termination region R2, an n-type semiconductor layer 20 is formed. Note that when the semiconductor device 1 is a diode, the trench gates 17 and the semiconductor layer 20 are not provided.

For example, the trench gates 17 are each formed such that polysilicon is filled in a trench extending through the fifth semiconductor part 15 and the sixth semiconductor part 16 and terminating in the first semiconductor part 11. Each trench gate 17 is electrically insulated from the first semiconductor part 11, the fifth semiconductor part 15, and the sixth semiconductor part 16 by a gate insulation film 18.

The first electrode 21 is provided over the entire region including the cell region R1 and the termination region R2 on the back surface of the semiconductor layer 10. When the semiconductor device 1 is an IGBT or an IEGT, the first electrode 21 is a collector electrode. When the semiconductor device 1 is a diode, the first electrode 21 is a cathode electrode.

The second electrode 22 is provided on the front surface of the semiconductor layer 10 via a first insulation film 31. When the semiconductor device 1 is an IGBT or an IEGT, the second electrode 22 is an emitter electrode. When the semiconductor device 1 is a diode, the second electrode 22 is an anode electrode.

The third electrode 23 is provided on the front surface of the semiconductor layer 10 via the first insulation film 31. When the semiconductor device 1 is an IGBT or an IEGT, the third electrode 23 is a gate electrode.

The third electrode 23 opposes a conductor 24 across the first insulation film 31. The third electrode 23 is electrically connected to the conductor 24 via a contact via 25. The conductor 24 is electrically connected to each trench gate 17. Therefore, a potential of each trench gate 17 is controlled with the applied voltage of the third electrode 23. When the applied voltage exceeds a threshold voltage, a channel is formed in the fifth semiconductor part 15. As a result, a current flows between the first electrode 21 and the second electrode 22 so that the semiconductor device 1 turns into an ON-state.

As shown in FIG. 2, in the semiconductor device 1, the second insulation film 32 is provided so as to be continuous with the first insulation film 31 in the termination region R2. The thickness of the second insulation film 32 is smaller than the thickness of the first insulation film 31. The first insulation film 31 and the second insulation film 32 are, for example, a silicon oxide film (SiO₂). For example, the second insulation film 32 can be formed by subjecting an insulation film having the same thickness as that of the first insulation film 31 to dry etching or wet etching.

Further, in the semiconductor device 1, a semi-insulation film 40 is provided on each of the first insulation film 31, the second insulation film 32, the third electrode 23, and the second electrode 22. A planner shape of the semi-insulation film 40 is a ring shape continuously surrounding the cell region R1. The resistivity of the semi-insulation film 40 is higher than the resistivity of the semiconductor layer 10 and is lower than the resistivity of the first insulation film 31 and the second insulation film 32. The semi-insulation film 40 includes, for example, nitrogen and silicon. The composition ratio of nitrogen in the semi-insulation film 40 is preferably equal to or higher than 40% and equal to or lower than 55%.

Moreover, in the semiconductor device 1, a protective film 50 is provided on the semi-insulation film 40. The protective film 50 is formed, for example, using resin such as polyimide.

In the semiconductor device 1 configured as described above, the semi-insulation film 40 contacts the second electrode 22 and the third electrode 23. The resistivity of the semi-insulation film 40 is not low enough to cause a short circuit between the second electrode 22 and the third electrode 23 during the operation of the semiconductor device 1. That is, during the operation of the semiconductor device 1, a current in magnitude that affects the operation of the semiconductor device 1 does not flow from the third electrode 23 to the second electrode 22 having a lower potential as compared to the third electrode 23, through the semi-insulation film 40.

Meanwhile, when a high electric field is generated in the termination region R2 externally from the protective film 50, electrons flow to the third electrode 23 through the semi-insulation film 40. Therefore, the electrons are less likely to be accumulated in the semi-insulation film 40.

Further, in the semiconductor device 1, when the thickness of the second insulation film 32 is large, since the electrons are less likely to tunnel through the second insulation film 32, the holes are more likely to be trapped in the semi-insulation film 40 by the electrons flowing in the vicinity of the interface with the second insulation film 32 in the semiconductor layer 10. When the number of holes trapped in the semi-insulation film 40 increases, the electric field distribution in the termination region R2 changes, which could cause fluctuation in the withstand voltage.

Thus, in the present embodiment, the thickness of the second insulation film 32 provided between the second semiconductor part 12 and the semi-insulation film 40 is smaller than the thickness of the first insulation film 31. Therefore, since some electrons are tunneled through the semiconductor layer 10, the electrons and holes are more unlikely to be excessively trapped in the semi-insulation film 40.

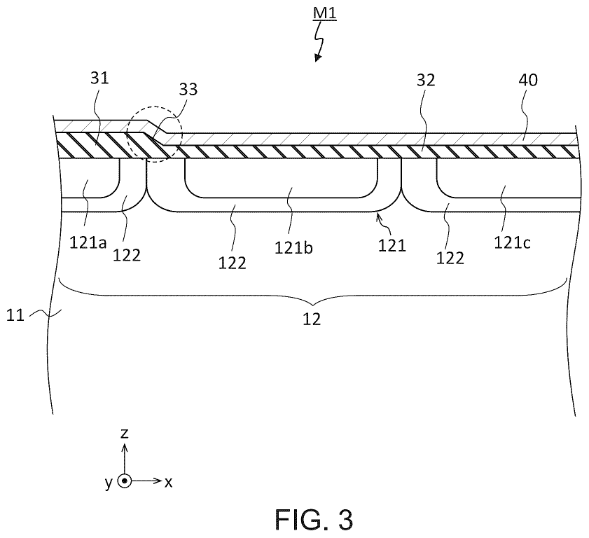

However, the withstand voltage of the semiconductor device 1 could change depending on the position of an end portion 33, which contacts the second insulation film 32, of the first insulation film 31, in other words, a step portion of the semi-insulation film 40 that is formed in accordance with the change in thickness from the first insulation film 31 to the second insulation film 32. Here, with reference to FIG. 3 to FIG. 8, the results of a TCAD (Technology Computer Aided Design) simulation of withstand voltage characteristics when the position of the end portion 33 of the first insulation film 31 is changed will be described.

FIG. 3 is a cross sectional view showing the structure of a first simulation model. A first simulation model M1 shown in FIG. 3 corresponds to the semiconductor device 1 according to the present embodiment. In the first simulation model M1, a diffusion region 122 is formed around each concentration peak region 121. The diffusion region 122 is a region of a p-type impurity injected to the concentration peak region 121 thermally diffused. The p-type impurity concentration in the diffusion region 122 is lower than the p-type impurity concentration in the concentration peak region 121.

The diffusion region 122 may be formed in the actual semiconductor device 1. In FIG. 3, the end portion 33 of the first insulation film 31, that is, the step portion where the height position of the semi-insulation film 40 changes is positioned between a first concentration peak region 121a, which is the closest to the cell region R1 among the plurality of concentration peak regions 121 and contacts the third semiconductor part 13, and a second concentration peak region 121b positioned on an outer side of the first concentration peak region 121a.

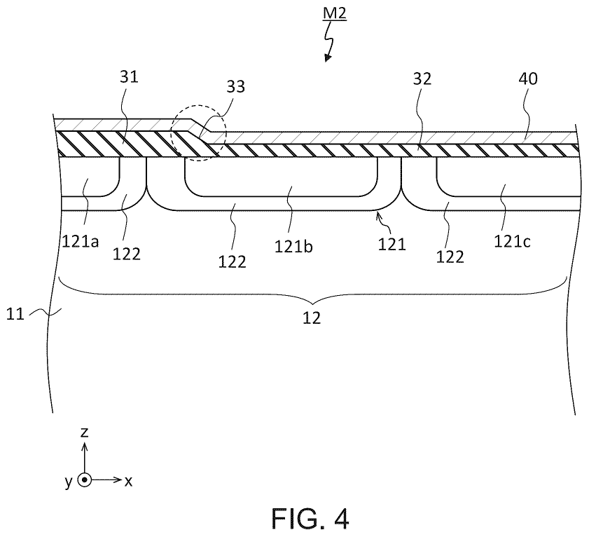

FIG. 4 is a cross sectional view showing the structure of a second simulation model. In a second simulation model M2 shown in FIG. 4, the position of the end portion 33 of the first insulation film 31 is shifted in a direction (right direction) toward the termination region R2 from the cell region R1 as compared to the first simulation model M1. As a result, the position of the end portion 33 of the first insulation film 31 moves to be on a left half portion of the second concentration peak region 121b.

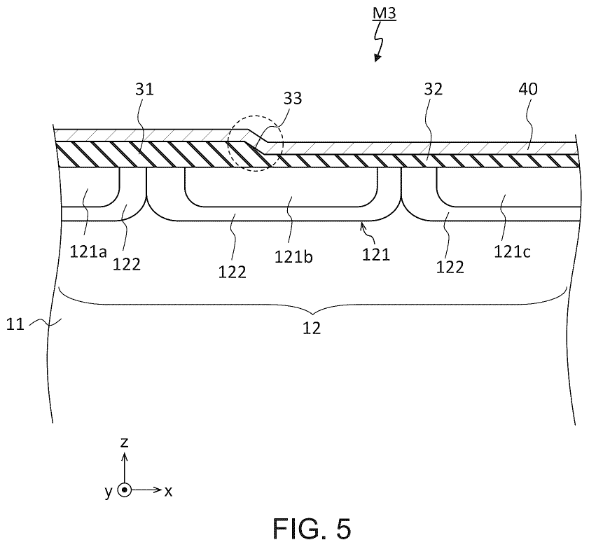

FIG. 5 is a cross sectional view showing the structure of a third simulation model. In a third simulation model M3 shown in FIG. 5, the position of the end portion 33 of the first insulation film 31 is further shifted in the right direction as compared to the second simulation model M2. As a result, the position of the end portion 33 of the first insulation film 31 moves to be on a center portion of the second concentration peak region 121b.

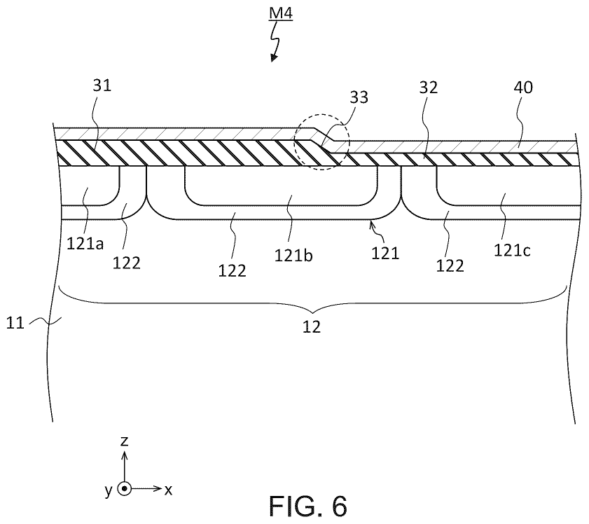

FIG. 6 is a cross sectional view showing the structure of a fourth simulation model. In a fourth simulation model M4 shown in FIG. 6, the position of the end portion 33 of the first insulation film 31 is further shifted in the right direction as compared to the third simulation model M3. As a result, the position of the end portion 33 of the first insulation film 31 moves to be on a right half portion of the second concentration peak region 121b.

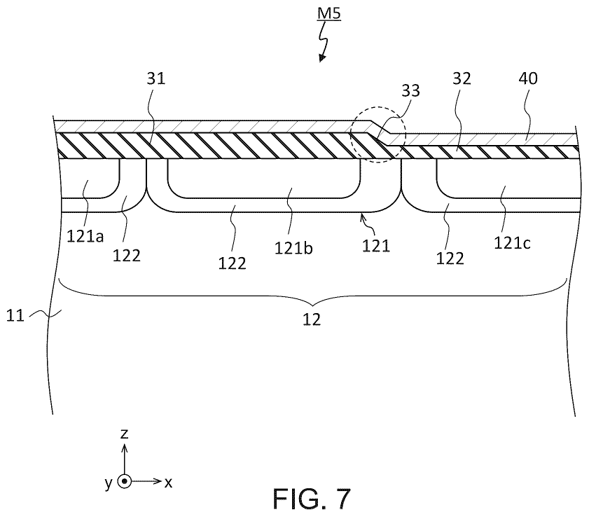

FIG. 7 is a cross sectional view showing the structure of a fifth simulation model. In a fifth simulation model M5 shown in FIG. 7, the position of the end portion 33 of the first insulation film 31 is further shifted in the right direction as compared to the fourth simulation model M4. As a result, the end portion 33 of the first insulation film 31 moves to be positioned between the second concentration peak region 121b and a third concentration peak region 121c positioned on an outer side of the second concentration peak region 121b.

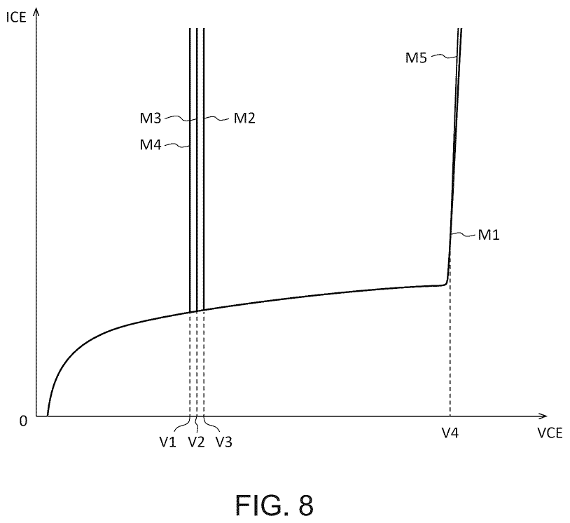

FIG. 8 is a graph showing the results of the TCAD simulation of the withstand voltage characteristics using each simulation model. In FIG. 8, the lateral axis represents a collector-emitter voltage VCE and the longitudinal axis represents a collector-emitter current ICE. Note that in this simulation, an OFF-state in which the gate-emitter voltage is lower than a threshold voltage is set as the condition.

According to the simulation results shown in FIG. 8, a breakdown voltage V1 of the fourth simulation model M4, a breakdown voltage V2 (>V1) of the third simulation model M3, and a breakdown voltage V3 (>V2) of the second simulation model M2 are lower than a breakdown voltage V4 of the first simulation model M1 and the fifth simulation model M5.

In the termination region R2, the concentration peak region 121 having a higher p-type impurity concentration and the end portion 33 of the first insulation film 31 (step portion of the semi-insulation film 40) have a higher electric field intensity. Therefore, the second simulation model M2, the third simulation model M3, and the fourth simulation model M4 have a structure in which the end portion 33 of the first insulation film 31 and the concentration peak region 121 overlap with each other and thus, mutually intensify the electric field intensity. As a result, the withstand voltage is reduced.

By contrast, in the first simulation model M1 and the fifth simulation model M5, the end portion 33 of the first insulation film 31 is positioned between the concentration peak regions 121, with no overlap between the end portion 33 of the first insulation film 31 and the concentration peak region 121. That is, the step portion of the semi-insulation film 40 is positioned outside the concentration peak region 121. This can suppress the reduction in the withstand voltage.

As described above, according to the present embodiment, since the position of the end portion 33 of the first insulation film 31, in other words, the step portion of the semi-insulation film 40 is optimized, the reduction in the withstand voltage can be suppressed while reducing the termination region R2.

Further, in the present embodiment, the end portion 33 of the first insulation film 31 is in a tapered shape. That is, the end portion 33 is inclined so as to be gradually reduced in thickness toward the front surface of the semiconductor layer 10. This mitigates the electric field intensity in the end portion so that the reduction in the withstand voltage can be further suppressed.

### Second Embodiment

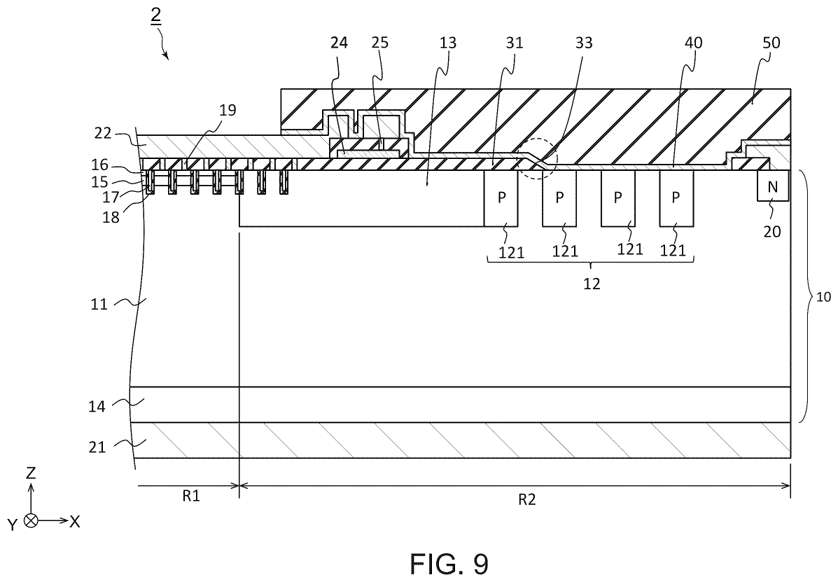

FIG. 9 is a cross sectional view of a semiconductor device according to a second embodiment. In FIG. 9, the same constituent elements as those of the semiconductor device 1 according to the aforementioned first embodiment are assigned the same reference signs and overlapping descriptions will be omitted.

A semiconductor device 2 according to the second embodiment differs from the semiconductor device 1 according to the first embodiment in that it does not include the second insulation film 32. In the semiconductor device 2 according to the present embodiment, the semi-insulation film 40 contacts the front surface of the semiconductor layer 10 at a position opposing the second semiconductor part 12.

Meanwhile, in the semiconductor device 2 according to the present embodiment, as with the first embodiment, the end portion 33 of the first insulation film 31 is positioned between the concentration peak region 121 contacting the third semiconductor part 13 and another concentration peak region 121 adjacent to the concentration peak region 121 in the X-direction. Therefore, the step portion of the semi-insulation film 40 is also positioned outside the concentration peak region 121. Thus, the reduction in the withstand voltage can be suppressed.

Therefore, according to the present embodiment, even without the second insulation film 32 being formed, the position of the end portion 33 of the first insulation film 31, in other words, the step portion of the semi-insulation film 40 is optimized. Thus, also in the present embodiment, the reduction in the withstand voltage can be suppressed while reducing the termination region R2.

Further, also in the present embodiment, since the end portion 33 of the first insulation film 31 is in a tapered shape, the electric field intensity in the end portion is mitigated. As a result, the reduction in the withstand voltage can be further suppressed.

Note that in the termination region R2 of the semiconductor device 2 according to the present embodiment, the diffusion region 122 described in the first embodiment may be provided around the concentration peak region 121. In this case, the end portion 33 of the first insulation film 31 is positioned on the diffusion region 122.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer including a cell region and a termination region that surrounds the cell region;
a first insulation film provided on the semiconductor layer; and
a semi-insulation film provided on the first insulation film,
wherein
the semiconductor layer includes:
a first semiconductor part of a first conductive type provided in the cell region and the termination region; and
a second semiconductor part of a second conductive type provided on the first semiconductor part in the termination region, the second semiconductor part including a plurality of concentration peak regions having a highest concentration of an impurity of the second conductive type in the second semiconductor part, and
an end portion on a side of the termination region of the first insulation film is positioned between any two of the plurality of concentration peak regions.

2. The semiconductor device according to claim 1, further comprising a second insulation film provided between the semi-insulation film and the second semiconductor part in the termination region,
wherein a thickness of the second insulation film is smaller than a thickness of the first insulation film.

3. The semiconductor device according to claim 1, wherein the semi-insulation film contacts the semiconductor layer at a position opposing the second semiconductor part in the termination region.

4. The semiconductor device according to claim 1, wherein
the second semiconductor part further comprises a diffusion region of the impurity of the second conductive type provided around each of the concentration peak regions, and
the end portion is positioned on the diffusion region.

5. The semiconductor device according to claim 2, wherein
the second semiconductor part further comprises a diffusion region of the impurity of the second conductive type provided around each of the concentration peak regions, and
the end portion is positioned on the diffusion region.

6. The semiconductor device according to claim 3, wherein
the second semiconductor part further comprises a diffusion region of the impurity of the second conductive type provided around each of the concentration peak regions, and
the end portion is positioned on the diffusion region.

7. The semiconductor device according to claim 1, wherein the end portion is positioned between a first concentration peak region and a second concentration peak region, the first concentration peak region being closest to the cell region among the plurality of concentration peak regions, the second concentration peak region being positioned on an outer side of the first concentration peak region.

8. The semiconductor device according to claim 2, wherein the end portion is positioned between a first concentration peak region and a second concentration peak region, the first concentration peak region being closest to the cell region among the plurality of concentration peak regions, the second concentration peak region being positioned on an outer side of the first concentration peak region.

9. The semiconductor device according to claim 3, wherein the end portion is positioned between a first concentration peak region and a second concentration peak region, the first concentration peak region being closest to the cell region among the plurality of concentration peak regions, the second concentration peak region being positioned on an outer side of the first concentration peak region.

10. The semiconductor device according to claim 1, wherein
the semi-insulation film comprises silicon and nitrogen, and
a composition ratio of the nitrogen in the semi-insulation film is equal to or higher than 40% and equal to or lower than 55%.

11. The semiconductor device according to claim 2, wherein
the semi-insulation film comprises silicon and nitrogen, and
a composition ratio of the nitrogen in the semi-insulation film is equal to or higher than 40% and equal to or lower than 55%.

12. The semiconductor device according to claim 3, wherein
the semi-insulation film comprises silicon and nitrogen, and
a composition ratio of the nitrogen in the semi-insulation film is equal to or higher than 40% and equal to or lower than 55%.

13. The semiconductor device according to claim 7, wherein
the semiconductor layer further comprises a third semiconductor part of the second conductive type contacting the first concentration peak region in the termination region, and
the concentration of the impurity in the third semiconductor part is higher than the concentration of the impurity in the first concentration peak region.

14. The semiconductor device according to claim 1, wherein a planner shape of each of the concentration peak regions is a frame shape continuously surrounding the cell region.

15. The semiconductor device according to claim 1, wherein an interval between the concentration peak regions is reduced as the concentration peak regions becomes further away from the cell region.

16. The semiconductor device according to claim 1, wherein a resistivity of the semi-insulation film is higher than a resistivity of the semiconductor layer and lower than a resistivity of the first insulation film.

17. The semiconductor device according to claim 3, wherein the end portion is positioned between a second concentration peak region and a third concentration peak region, the second concentration peak region being positioned on an outer side of a first concentration peak region that is closest to the cell region among the plurality of concentration peak regions, the third concentration peak region being positioned on an outer side of the second concentration peak region.

18. The semiconductor device according to claim 1, further comprising:
a first electrode provided on a back surface side of the semiconductor layer; and
a second electrode and a third electrode that are provided on a front surface side of the semiconductor layer,
wherein the semi-insulation film contacts the second electrode and the third electrode.

19. The semiconductor device according to claim 18, wherein the semiconductor device is an IGBT (Insulated Gate Bipolar Transistor) or an IEGT (Injection Enhanced Gate Transistor).

20. The semiconductor device according to claim 1, wherein the first conductive type is an n-type and the second conductive type is a p-type.
